(19) United States
(12) Patent Application Publication
(10) Pub. No.: US 2021/0294157 A1
(43) Pub. Date: Sep. 23, 2021

(54) ARRAY SUBSTRATE, DISPLAY DEVICE AND DISPLAY METHOD THEREFOR

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Weixiong CHEN, Beijing (CN); Le ZHANG, Beijing (CN); Hanqing LIU, Beijing (CN); Xin LI, Beijing (CN); Yong SONG, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 17/264,867

(22) PCT Filed: Jun. 29, 2020
(86) PCT No.: PCT/CN2020/098855

§ 371 Date: Feb. 1, 2021

(30) Foreign Application Priority Data
Jul. 5, 2019 (CN) 201910605630.4

(51) Int. Cl. G02F 1/1335; H01L 27/12; H01L 41/09; G02F 1/133

(52) U.S. Cl. CPC G02F 1/133553; G02F 1/13312; H01L 41/0973; H01L 27/1255

(57) ABSTRACT

An array substrate, including: a base substrate, a plurality of pixel units, a reflective layer, and a dielectric elastomer. The plurality of pixel units are located on the base substrate, and at least one of the plurality of pixel units includes the reflective layer; and the dielectric elastomer is located on a side of the reflective layer close to the base substrate, and is configured to change the unevenness of a surface on a side close to the reflective layer under the action of a voltage, thereby changing the unevenness of the reflective layer. Further provided are a display device and a display method therefor.

The present application claims priority of the Chinese Patent Application No. 201910605630.4, filed on Jul. 5, 2019, the disclosure of which is incorporated herein by reference in its entirety as part of the present application.

### TECHNICAL FIELD

The embodiments of the present disclosure relate to an array substrate, a display device and a display method thereof.

### BACKGROUND

A liquid crystal display is generally formed by celling an upper substrate and a lower substrate, and liquid crystal is encapsulated in a space between the two substrates. Because the liquid crystal molecules themselves do not emit light, the display needs a light source in order to display images. According to a type of an employed light source, the liquid crystal display can be classed to a transmissive liquid crystal display, a reflective liquid crystal display, and a transflective liquid crystal display. A backlight source serves as the light source of the transmissive liquid crystal display, and the light emitted by the backlight source passes through a transparent electrode and a liquid crystal layer to display images, which can display images in a dark environment. Ambient light serves as the light source of the reflective liquid crystal display, and the ambient light enters the display screen and then is reflected so as to display images, therefore, the reflective liquid crystal display cannot display images in the dark environment. The transflective liquid crystal display has the characteristics of both the transmissive liquid crystal display and the reflective liquid crystal display. Both of a transmissive region and a reflective region are arranged in a panel, which can be applied not only in the bright environment but also in the dark environment.

### SUMMARY

The embodiments of the present disclosure provide an array substrate, a display panel, a display device and a display method thereof.

At least one embodiment of the present disclosure provides an array substrate, including: a base substrate; a plurality of pixel units on the base substrate, at least one of the plurality of pixel units including a reflective layer; and a dielectric elastomer, on a side of the reflective layer close to the base substrate, and configured to change an unevenness of a surface on a side close to the reflective layer under a voltage, thereby changing an unevenness of the reflective layer.

In some examples, the reflective layer is conformally formed on the dielectric elastomer.

In some examples, at least one of the plurality of pixel units further includes a transmissive region located outside the reflective layer.

In some examples, the array substrate further includes a control line, electrically connected to the dielectric elastomer, and configured to apply a voltage to the dielectric elastomer.

In some examples, the dielectric elastomer includes a plurality of dielectric elastomer blocks arranged in an array, and each of the dielectric elastomer blocks is in a region where at least one pixel unit is located, the control line includes a plurality of control lines, and each of the dielectric elastomer blocks is connected to at least one of the plurality of control lines.

In some examples, the dielectric elastomer is provided with a light transmitting region in a region corresponding to the transmissive region.

In some examples, the dielectric elastomer includes a conductive layer and a dielectric elastic material layer which are stacked, the conductive layer is electrically connected to the control line, and is configured to apply a voltage to the dielectric elastic material layer, the dielectric elastic material layer is configured to change an unevenness of a surface on a side away from the base substrate according to the voltage applied by the conductive layer.

In some examples, the conductive layer includes a first conductive layer and a second conductive layer, respectively located on two sides of the dielectric elastic material layer in a direction perpendicular to the base substrate, one of the first conductive layer and the second conductive layer is electrically connected to the control line, and the other of the first conductive layer and the second conductive layer is configured to apply a common voltage.

In some examples, changing the unevenness of the surface close to the reflective layer includes forming a protrusion or changing a height of the protrusion.

In some examples, the reflective layer is a color reflective layer.

In some examples, the dielectric elastomer and the reflective layer are insulated from each other.

At least one embodiment of the present disclosure provides a display device, including the above-mentioned array substrate.

In some examples, the display device further includes a controller and a photosensitive element, wherein the controller is respectively electrically connected to the photosensitive element and the dielectric elastomer, the photosensitive element is configured to detect ambient light intensity and provide a light intensity signal to the controller, and the controller applies a corresponding voltage to the dielectric elastomer according to the light intensity signal.

At least one embodiment of the present disclosure provides a display method of the display device, including: detecting the ambient light intensity; applying a corresponding voltage to the dielectric elastomer according to the light intensity to change an unevenness of a surface on a side of the dielectric elastomer close to the reflective layer, thereby changing reflectivity of the reflective layer.

In some examples, at least one of the plurality of pixel units includes a transmissive region, and the display device further includes a backlight unit, applying a corresponding voltage to the dielectric elastomer according to the light intensity includes: when the light intensity is less than a first preset light intensity, switching on the backlight unit and stopping applying the voltage to the dielectric elastomer; when the light intensity is greater than or equal to the first preset light intensity and less than a second preset light intensity, applying a voltage in a first voltage range to the dielectric elastomer, so that the unevenness of the surface of the dielectric elastomer is greater than a preset unevenness; when the light intensity is greater than or equal to the second preset light intensity, applying a voltage in a second voltage range to the dielectric elastomer, so that the unevenness of the surface of the dielectric elastomer is less than the preset unevenness, wherein the second preset light intensity is greater than the first preset light intensity, and a voltage value in the first voltage value range is greater than a voltage value in the second voltage value range.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic structural diagram of an array substrate according to at least one embodiment of the present disclosure;

FIG. 2 is a schematic cross-sectional structural view of the array substrate illustrated in FIG. 1 along the line A-A;

FIG. 3 is a schematic structural diagram of another array substrate according to at least one embodiment of the present disclosure;

FIG. 4 is a schematic cross-sectional structural view of an array substrate illustrated in FIG. 3 along the line B-B′;

FIG. 5 is a schematic structural diagram of another array substrate according to at least one embodiment of the present disclosure;

FIG. 6 is a schematic diagram of a block design of a dielectric elastomer of an array substrate according to at least one embodiment of the present disclosure;

FIG. 7 is a schematic structural diagram of a dielectric elastomer block according to at least one embodiment of the present disclosure;

FIG. 8 is a schematic diagram of a protrusion of a dielectric elastomer according to at least one embodiment of the present disclosure;

FIG. 9 is a color reflective layer pattern according to at least one embodiment of the present disclosure;

FIG. 10 is a schematic structural diagram of a display panel according to at least one embodiment of the present disclosure;

FIG. 11 is a schematic diagram of block control of a display device according to at least one embodiment of the present disclosure;

FIG. 12A is a schematic structural diagram of the dielectric elastomer and the reflective layer when no voltage is applied to the dielectric elastomer according to at least one embodiment of the present disclosure;

FIG. 12B is a schematic structural diagram of the dielectric elastomer and the reflective layer when a voltage in a first voltage range is applied to the dielectric elastomer according to at least one embodiment of the present disclosure; and

FIG. 12C is a schematic diagram of a protrusion of the dielectric elastomer and the reflective layer when a voltage in a second voltage range is applied to the dielectric elastomer according to at least one embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Similarly, similar words such as “a”, “an” or “the” do not indicate the limitation of quantity, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “Upper”, “lower”, “left”, “right”, etc. are only used to indicate the relative positional relationship, and when the absolute position of the object to be described is changed, the relative positional relationship may also change accordingly.

The technical principle of the transflective liquid crystal display is to arrange a transmissive region in a reflective metal, divide each pixel into a transmissive part and a reflective part, and introduce a backlight source to achieve transflective effect. In a bright environment, the reflective metal of the reflective part reflects ambient light for display; in a dark environment, the light from the backlight source is utilized to display in a transmissive mode.

However, the transflective liquid crystal display also has some problems. For example, due to the transmissive region, an area of the reflective region will be reduced accordingly, so that its reflectivity in the bright environment will be decreased; if the area of the reflective region is increased, an area of the transmissive region will be reduced, so that its transmittance in the dark environment will also be decreased.

The embodiments of the present disclosure provide an array substrate, a display panel, a display device and a display method thereof. The array substrate can increase the reflectivity without reducing the area of the transmissive region, and can adjust its own reflectivity according to the ambient light intensity, thereby optimizing the display effect.

The embodiments of the present disclosure will be described in detail below with reference to the accompanying drawings. It should be noted that the same reference signs in different drawings refer to the same or similar elements that have been described.

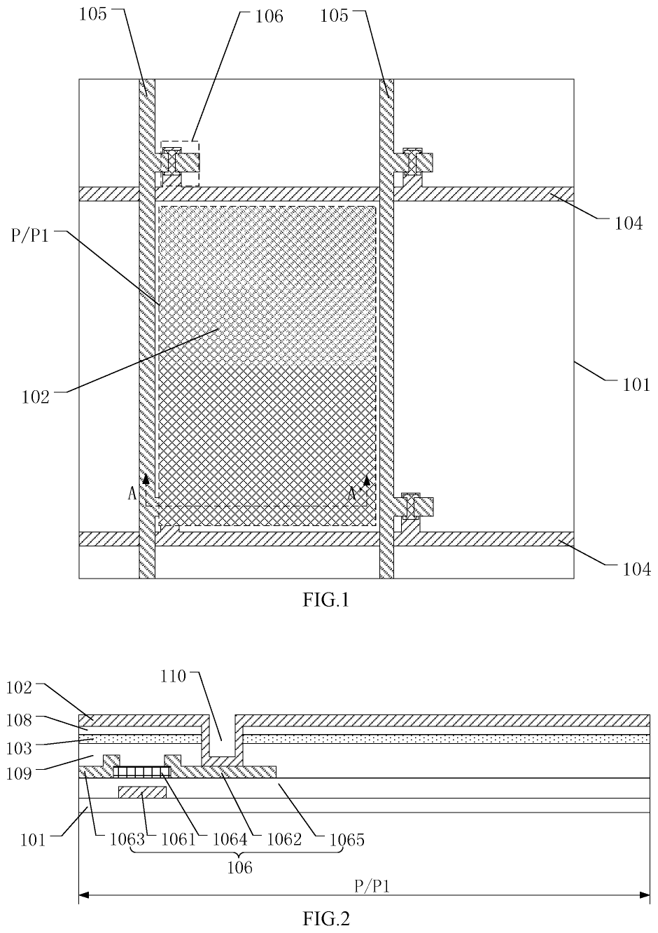

FIG. 1 is a schematic structural diagram of an array substrate according to at least one embodiment of the present disclosure, and FIG. 2 is a schematic cross-sectional structural view of the array substrate illustrated in FIG. 1 along the line A-A′.

As illustrated in FIGS. 1 and 2, at least one embodiment of the present disclosure provides an array substrate, which can be applied in the reflective liquid crystal display panel. The array substrate includes: a base substrate 101, a plurality of pixel units P, a reflective layer 102 and a dielectric elastomer 103. The plurality of pixel units P are located on the base substrate 101, and at least one of the plurality of pixel units P includes a reflective region P1. The reflective region P1 includes a reflective layer 102 configured to reflect light incident from the outside; the dielectric elastomer 103 is located on a side of the reflective layer 102 close to the base substrate 101, and is configured to change an unevenness of a surface on a side close to the reflective layer under a voltage, so as to change an unevenness of the reflective layer 102.

In the embodiment of the present disclosure, the unevenness is used to evaluate the unevenness degree of a surface. For example, the unevenness of a surface can be obtained by measuring height differences between a plurality of high points and a plurality of low points on the surface, and calculating an arithmetic average of the height differences. The height of the high point or the low point refers to the distance between a point on the surface and a reference plane. For example, the surface of the dielectric elastomer away from the reflective region is the reference plane, the point with a large distance is the high point, and the point with a small distance is the low point. However, the embodiments of the present disclosure are not limited to this, and other unevenness evaluation methods can also be applied provided that the unevenness of the surface can be evaluated.

The dielectric elastomer includes an electro-deformable elastomer material, which can change its shape or volume under an external electric field, and can restore its original shape or volume when the external electric field is removed. The embodiments of the present disclosure adjust the reflectivity of the array substrate by applying the dielectric elastomer to the array substrate, thereby improving the display effect.

In some examples, the reflective layer 102 is conformally formed on the dielectric elastomer 103. That is, the reflective layer 102 is configured to deform as the dielectric elastomer 103 deforms, and is consistent with the deformation of the surface on the side of the dielectric elastomer 103 close to the reflective layer 102. In this way, when the unevenness of the surface on the side of the dielectric elastomer 103 close to the reflective layer 102 is changed under the voltage, the unevenness of the surface of the reflective layer 102 can be changed.

For example, the whole dielectric elastomer 103 can be deformed, so that the unevenness of the surface on the side of the dielectric elastomer 103 close to the reflective layer 102 is changed.

In some examples, the unevenness of the surface of the dielectric elastomer 103 is positively correlated with the voltage applied to it. That is, the higher the voltage applied to the dielectric elastomer, the greater its surface unevenness. In the array substrate according to at least one embodiment of the present disclosure, because the unevenness of the surface on a side of the dielectric elastomer close to the reflective layer can be changed under the voltage so that the unevenness of the surface of the reflective layer is changed to change the reflectivity of the reflective layer, therefore the display effect of the display panel using the array substrate can be improved.

In some examples, the base substrate 101 can be a transparent or non-transparent insulation substrate. For example, the base substrate 101 can be a glass substrate or a quartz substrate, or a substrate made of other suitable materials.

In some examples, as illustrated in FIGS. 1 and 2, the array substrate further includes a gate line 104, a data line 105 and a switch element 106. The gate line 104 and the data line 105 are located on the base substrate 101 and cross each other and are insulated from each other to define a plurality of pixel units P; the switch element 106 is located in the pixel unit P and is connected to the gate line 104 and the data line 105. In addition, as illustrated in FIG. 2, the switch element 106 is located on a side of the dielectric elastomer 103 close to the base substrate 101.

In some examples, as illustrated in FIG. 2, the switch element 106 is a thin film transistor, and includes a gate electrode 1061, a source electrode 1063, a drain electrode 1062, a semiconductor layer 1064, and a gate insulation layer 1065. The semiconductor layer 1063 is located directly above the gate electrode 1061 and is connected to the source electrode 1063 and the drain electrode 1062 respectively. The gate insulation layer 1065 covers the gate electrode 1061 and is configured to insulate the gate electrode 1061 from the source electrode 1063, the drain electrode 1062 and the semiconductor layer 1064.

It should be noted that FIG. 2 only illustrates an example in which the thin film transistor is a bottom-gate thin film transistor, but it can also be other types of thin film transistors, such as a top-gate thin film transistor, a double-gate thin film transistor, and the like.

In some examples, the array substrate further includes a first insulation layer 108. As illustrated in FIG. 2, the first insulation layer 108 is located between the reflective layer 102 and the dielectric elastomer 103, and is configured to insulate the reflective layer 102 from the dielectric elastomer 103, and does not affect conformity of the reflective layer 102 and the dielectric elastomer 103. That is, the first insulation layer 108 can be conformally formed on the dielectric elastomer 103, and the reflective layer 102 can be conformally formed on the first insulation layer 108. Therefore, the first insulation layer can be made of a material with a low hardness, and the thickness of the first insulation layer can be set small without affecting the insulation.

In some examples, as illustrated in FIG. 2, the array substrate further includes a second insulation layer 109. The second insulation layer 109 is located between the switch element 106 and the dielectric elastomer 103 and covers the switch element 106, and the second insulation layer 109 is configured to insulate the switch element 106 from the dielectric elastomer 103.

In some examples, both of the first insulation layer 108 and the second insulation layer 109 can be transparent or non-transparent insulation layers.

In some examples, the reflective layer 102 is a conductive reflective layer. For example, a material of the reflective layer 102 can be a metal conductive material such as silver, copper, aluminum, molybdenum, or other suitable materials.

In some examples, the array substrate further includes a first via hole 110 located on the first insulation layer 108 and passing through the dielectric elastomer 103 and the second insulation layer 109, so that the reflective layer 102 is electrically connected to one of the source electrode and drain electrode of the thin film transistor by the first via hole 110, and the data line 105 is electrically connected to the other of the source electrode and the drain electrode. In the example illustrated in FIG. 2, the reflective layer 102 is electrically connected to the drain electrode 1062, the data line 105 is electrically connected to the source electrode 1063, and the gate line 104 is electrically connected to the gate electrode 1061. The switch element 106 is configured to turn on or turn off the electrical connection between the data line 105 and the reflective layer 102 according to the scan signal provided by the gate line 104. In this way, the reflective layer 102 functions as a pixel electrode, that is, the reflective layer 102 provides a pixel voltage to the pixel unit P.

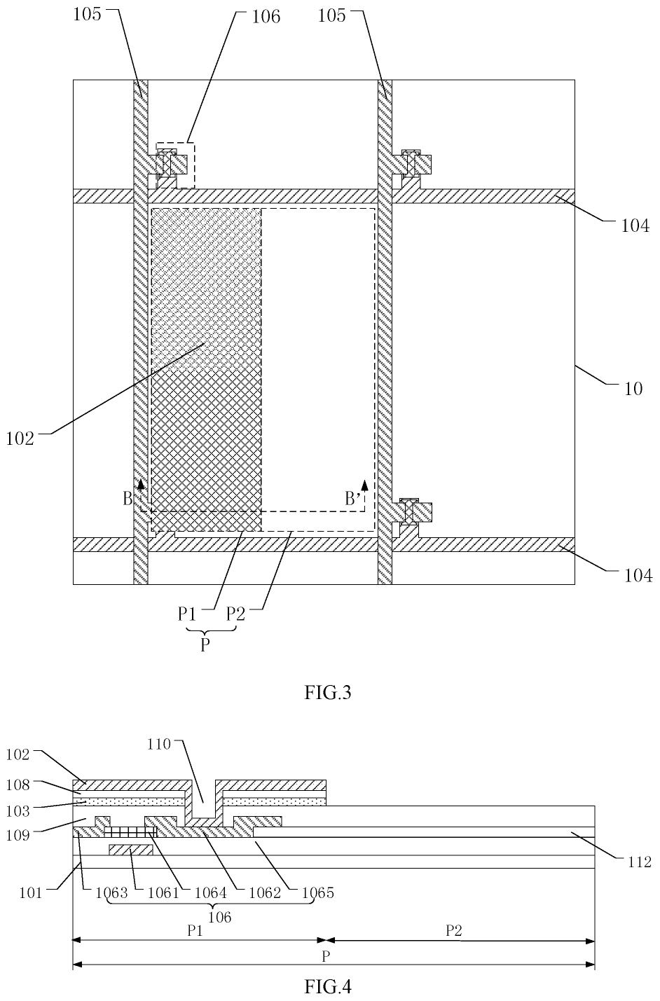

In some examples, the array substrate of at least one embodiment of the present disclosure can also be applied in the transflective liquid crystal display panel. FIG. 3 is a schematic structural diagram of another array substrate according to at least one embodiment of the present disclosure, and FIG. 4 is a schematic cross-sectional structural view of the array substrate illustrated in FIG. 3 along the line B-B′. The array substrate illustrated in FIG. 3 is similar with the structure of the array substrate illustrated in FIG. 1, and they differ with each other in that the pixel unit P of the array substrate illustrated in FIG. 3 further includes a transmissive region P2. Therefore, the same terms and reference signs refer to the elements having the same or similar structure.

As illustrated in FIGS. 3 and 4, at least one of the plurality of pixel units P further includes a transmissive region P2 located outside the reflective region P1, and the reflective region P1 and the transmissive region P2 constitute the pixel unit P. In the transmissive region P2, light can penetrate the array substrate. It should be noted that the reflective layer 102 is only located in the reflective region P1, and the transmissive region P2 does not include the reflective layer 102; a ratio of the area of the reflective region to the area of the transmissive region can be designed according to actual requirements, which is not limited in the present disclosure.

For the array substrate including the transmissive region, because the dielectric elastomer is arranged under the reflective layer of the reflective region, the reflectivity of the reflective region can adjusted by the dielectric elastomer without changing the ratio of the area of the reflective region to the area of the transmissive region.

In some examples, the array substrate further includes a transmissive electrode 112. The transmissive electrode 112 is electrically connected to the source electrode or drain electrode for driving the liquid crystal molecules located in the transmissive region to rotate. In the example illustrated in FIG. 4, the transmissive electrode 112 is electrically connected to the drain electrode 1062 and at least partially overlaps with the transmissive region P2 in a direction perpendicular to the base substrate 101. It should be noted that the transmissive electrode 112 and the reflective layer 102 can be located in the same layer and connected to each other.

For example, both of the reflective layer and the transmissive electrode in the above embodiments are electrically connected to the drain electrode, and can be inputted with display signals during displaying to provide pixel voltages to the liquid crystal molecules in the reflective region and transmissive region respectively, and thus function as the pixel electrode.

In some examples, because the array substrate includes the transmissive region, the base substrate 101, the first insulation layer 108, the gate insulation layer 1065, and the second insulation layer 109 are transparent insulation layers.

In some examples, the transmissive electrode 112 is made of a transparent conductive material. For example, it can be made of indium tin oxide (ITO), indium zinc oxide (IZO), indium gallium zinc oxide and other transparent metal oxides.

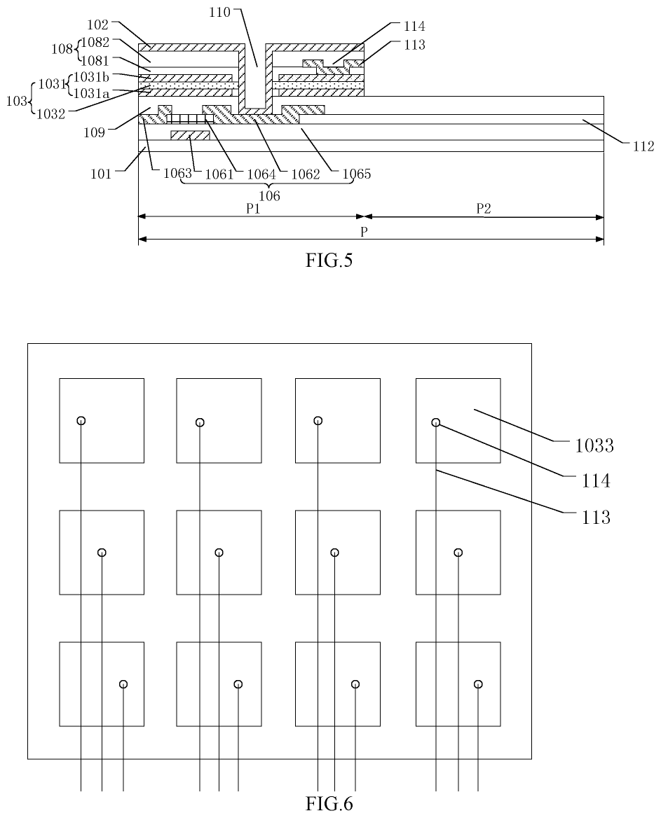

FIG. 5 is a schematic structural diagram of another array substrate according to at least one embodiment of the present disclosure. As illustrated in FIG. 5, the array substrate further includes a control line 113, located between the dielectric elastomer 103 and the reflective layer 102, electrically connected to the dielectric elastomer 103 and insulated from the reflective layer 102, and configured to apply an voltage to the dielectric elastomer 103, so as to control the dielectric elastomer 103 to change the unevenness of the surface on the side close to the reflective layer 102. In the display device using the array substrate, the control line can be connected to a controller, so that the amount of change of the unevenness of the surface of the dielectric elastomer can be controlled by controlling the voltage applied to the dielectric elastomer.

In some examples, as illustrated in FIG. 5, the dielectric elastomer 103 includes a conductive layer 1031 and a dielectric elastic material layer 1032 which are stacked. The conductive layer 1031 is electrically connected to the control line 113 through a second via hole 114. The conductive layer 1031 is configured to apply a voltage to the dielectric elastic material layer 1032; and the dielectric elastic material layer 1032 is configured to change the unevenness of the surface on the side close to the reflective layer according to the voltage applied by the conductive layer 1031. Both of the conductive layer 1031 and the reflective layer 102 are conformal with the dielectric elastic material layer 1032. Therefore, the conductive layer can be made of conductive materials with low hardness, and the thickness of the conductive layer can be set small without affecting the conductive effect. However, the embodiment of the present disclosure has no particular limitation on the hardness and thickness of the conductive layer, provided that the unevenness of the surface can be changed as the dielectric elastomer deforms.

In some examples, as illustrated in FIG. 5, the conductive layer 1031 includes a first conductive layer 1031a and a second conductive layer 1031b insulated from each other, the first conductive layer 1031a is located on the side of the dielectric elastic material layer 1032 close to the base substrate 101, and the second conductive layer 1031b is located on the side of the dielectric elastic material layer 1032 away from the base substrate 101. The second conductive layer 1031b is electrically connected to the control line 113 through the second via hole 114, and is applied with a first voltage by the control line 113; the first conductive layer 1031a is connected to a common power source and is configured to apply a common voltage. For example, the first conductive layer 1031a can be electrically connected to a peripheral power source through via holes in a peripheral region of a display region.

An example in which the first conductive layer and the second conductive layer are arranged on two sides of the dielectric elastic material layer respectively is illustrated above. However, the embodiments of the present disclosure are not limited thereto. For example, the first conductive layer and the second conductive layer can be arranged on a same side of the dielectric elastic material layer, and the first conductive layer and the second conductive layer are electrically insulated from each other and at least one of them is a patterned electrode, so that the a voltage can be applied between the first conductive layer and the second conductive layer to generate an electric field on the dielectric elastic material layer. For example, the first conductive layer is a patterned electrode, the second conductive layer is a plate electrode, and the first conductive layer is located between the second conductive layer and the dielectric elastic material layer. Alternatively, both of the first conductive layer and the second conductive layer are patterned electrodes, and the first conductive layer and the second conductive layer can be provided on a same layer or different layers. For example, in a case where the first conductive layer and the second conductive layer are located on a same side of the dielectric elastic material layer, they can be located on the side of the dielectric elastic material layer away from the reflective layer. In this way, the reflective layer can also be in direct contact with the dielectric elastic material layer, so that the deformation of the dielectric elastic material layer can be better transferred to the reflective layer.

In some examples, for example, a material of the control line 113 can be silver, silver alloy, copper, copper alloy, aluminum, aluminum alloy, and other suitable materials.

In some examples, a material of the dielectric elastic material layer 1032 can be silicon rubber, polyurethane or polyacrylate, or a composite material of silicon rubber, polyurethane or polyacrylate or other suitable materials. Different dielectric elastic materials have different properties. For example, polyacrylate has high energy density and is easy to process, but has high driving voltage and slow response speed; silicon rubber has a fast response speed and a wide applicable temperature range. Therefore, a suitable dielectric elastic material can be selected according to actual requirement, which is not limited in the present disclosure.

In some examples, as illustrated in FIG. 5, the first insulation layer 108 includes a first sub-insulation layer 1081 and a second sub-insulation layer 1082 which are stacked, and the first sub-insulation layer 1081 is located on a side of the second sub-insulation layer 1082 close to the dielectric elastomer 103, and the control line 113 is located between the first sub-insulation layer 1081 and the second sub-insulation layer 1082. The second via hole 114 is provided in the first sub-insulation layer 1081 so that the control line 113 is electrically connected to the second conductive layer 1031b of the dielectric elastomer 103.

It should be noted that the positions of the first conductive layer 1031a and the second conductive layer 1031b can be interchanged. In addition, although FIG. 5 illustrates that the control line 113 is located above the dielectric elastomer 103, the control line 113 can also be located below the dielectric elastomer 103, provided that one of the first conductive layer 1031a and the second conductive layer 1031b is connected to the control line 113, and the other of the first conductive layer 1031a and the second conductive layer 1031b is electrically connected to the common power source. When the control line 113 is located below the dielectric elastomer 103, with a structure similar to that illustrated in FIG. 5, the second insulation layer 109 can be divided into two insulation layers, and the control line 113 is located between the two insulation layers divided from the second insulation layer 109 and is electrically connected to one of the first conductive layer 1031a and the second conductive layer 1031b through the via hole.

In some examples, as illustrated in FIG. 5, the first via hole 110 passes through the second sub-insulation layer 1082, the first sub-insulation layer 1081, the second conductive layer 1031b, the dielectric elastic material layer 1032, and the first conductive layer 1031a, such that the reflective layer 102 is electrically connected to the drain electrode 1062 of the thin film transistor.

FIG. 6 is a schematic diagram of block design of a dielectric elastomer of an array substrate according to at least one embodiment of the present disclosure.

As illustrated in FIG. 6, the dielectric elastomer 103 is divided into a plurality of dielectric elastomer blocks 1033 arranged in an array and insulated from each other. The number of control lines 113 is plural, and the dielectric elastomer blocks 1033 are electrically connected to the control lines 113 in one-to-one correspondence. It should be noted that although FIG. 6 illustrates that the dielectric elastomer block 1033 is electrically connected to the control line 113 through one second via hole 114, the dielectric elastomer block 1033 can also be electrically connected to the control line 113 through a plurality of second via holes 114. The plurality of second via holes facilitate to achieve the electrical connection between the dielectric elastomer block and the control line, and the voltage signal loss can be reduced by the parallel connection between a plurality of connection points.

In some examples, each of the dielectric elastomer blocks 1033 covers at least one pixel unit P. The dielectric elastomer blocks 1033 and the pixel units P can be in one-to one correspondence, or one dielectric elastomer block 1033 can cover a plurality of pixel units P.

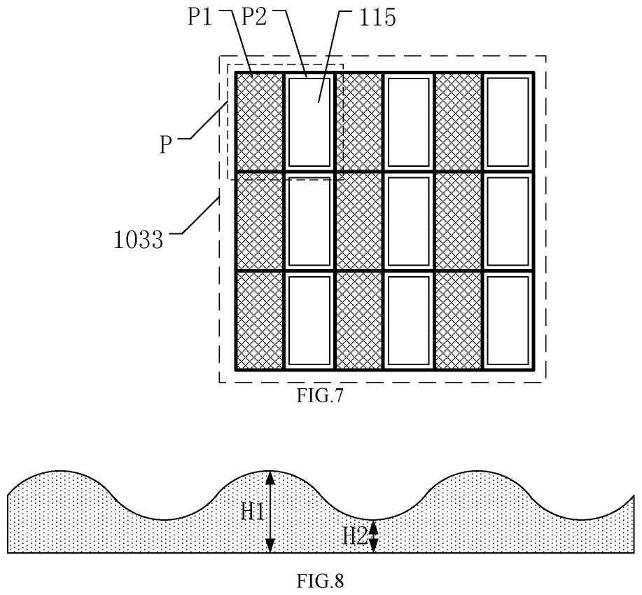

FIG. 7 is a schematic structural diagram of a dielectric elastomer block 1033 according to at least one embodiment of the present disclosure. FIG. 7 illustrates an example in which one dielectric elastomer block 1033 covers 9 pixel units P. As illustrated in FIG. 7, a region of the dielectric elastomer block 1033 corresponding to the transmissive region P2 is provided with a light transmitting region 115, that is, the region where the dielectric elastomer block 1033 overlaps with the transmissive region P2 in the direction perpendicular to the base substrate 101 is provided with the light transmitting region 115. For example, the light transmitting region 115 can be formed by opening a hole in the dielectric elastomer block 1033. An area of the light transmitting region 115 can be greater than, less than or equal to an area of the corresponding transmissive region P2. The light transmitting region 115 can avoid or reduce the influence of the dielectric elastomer block 1033 on the light transmitting property of the transmissive region P2.

By dividing the dielectric elastomer into a plurality of dielectric elastomer blocks, each of the dielectric elastomer blocks can be controlled independently, so that the reflectivity of different positions of the array substrate can be adjusted, so that the display effect of the display panel using the array substrate can be optimized.

In some examples, for the above dielectric elastomer 103, changing the unevenness of a surface on a side refers to forming a protrusion on the surface on a side or changing the height of the formed a protrusion. FIG. 8 is a schematic diagram of a protrusion of a dielectric elastomer according to at least one embodiment of the present disclosure. As illustrated in FIG. 8, a protrusion is formed on the surface on a side of the dielectric elastomer 103. H1 represents a thickness of the dielectric elastomer formed with a protrusion at a high point position, H2 represents a thickness of the dielectric elastomer formed with a protrusion at a low point position, and H1-H2 represents the height of a protrusion. The higher the height of the protrusion, the higher the unevenness of the surface and the higher the reflectivity.

It should be noted that the protrusion of the dielectric elastomer can also has other shapes, which are not limited in the present disclosure.

In some examples, a relationship between the height of the protrusion and the reflectivity is obtained by experimental methods in the present disclosure. Table 1 is a relationship table of the height of the protrusion and the reflectivity according to at least one embodiment of the present disclosure. It can be seen from Table 1 that the reflectivity will be significantly improved as the height of the protrusion increases. For example, when the height of the protrusion is 0, the reflectivity is 12%; when the height of the protrusion is 1.58 μm, the reflectivity is 38%.

TABLE 1

| | THICKNESS AT | HEIGHT OF | |
|---|---|---|---|
| SERIAL | LOW POINT H2/ | PROTRUSION/ | |
| NUMBER | μm | μm | REFLECTIVITY |
| S1 | 1.78 | 0.0 | 12% |
| S2 | 0.90 | 0.71 | 25% |
| S3 | 0.79 | 0.89 | 27% |
| S4 | 0.28 | 1.58 | 38% |

It should be noted that the above height of the protrusion, the reflectivity and the relationship of them are only illustrated as an example, which facilitates readers to understand. However, the height of the protrusion, the reflectivity, and the relationship of them are also affected by factors such as the materials of the dielectric elastomer and the reflective layer, and the voltage, and the like, and thus they are not limited to Table 1.

In some examples, for the array substrates illustrated in FIGS. 1 and 2 which can be applicable to a reflective liquid crystal display panel, the reflective layer can also be a color reflective layer to achieve color reflection, thereby achieving color display. In this way, when the array substrate is applied in a display panel, there is no need to provide a color filter layer on the substrate opposed to the array substrate, thereby simplifying the manufacturing process.

An implementation method of the color reflective layer can be, for example, coating photoresist of three colors, such as red, green, and blue, on the surface of the reflective layer, and etching the photoresist in different layers to obtain a color reflective layer pattern.

FIG. 9 is a color reflective layer pattern according to at least one embodiment of the present disclosure. As illustrated in FIG. 9, the reflective layers of three adjacent pixel units are a red reflective layer R, a green reflective layer and a blue reflective layer B, respectively. The reflective layers of all pixel units form a color reflective layer, thereby achieving color display.

At least one embodiment of the present disclosure further provides a display panel, including the array substrate of any of the above embodiments.

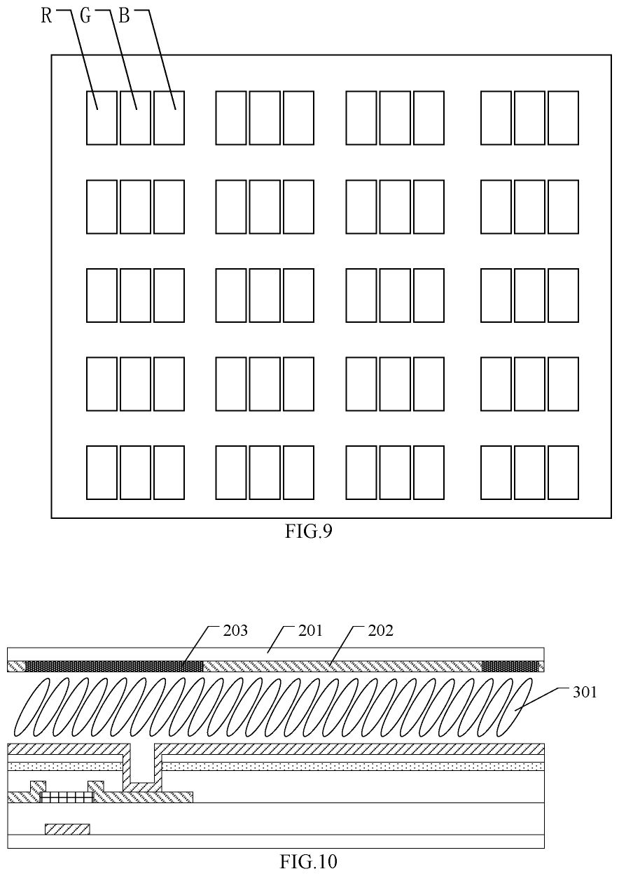

FIG. 10 is a schematic structural diagram of a display panel according to at least one embodiment of the present disclosure. As illustrated in FIG. 10, the display panel further includes an opposing substrate opposite to the array substrate and a liquid crystal layer 301 located between the array substrate and the opposing substrate. The opposing substrate includes a second base substrate 201, a color filter layer 202, and a black matrix 203. The color filter layer 202 and the black matrix 203 are arranged on the second base substrate 201, for example, on a side of the second base substrate 201 facing the array substrate.

In some examples, for the array substrate using the above color reflective layer, because the array substrate is provided with the color reflective layer, which can function as color display, the opposing substrate can also not provided with the color filter layer 202.

The display panel according to at least one embodiment of the present disclosure has the same beneficial effects as the array substrate of the above embodiments, which will not be repeated here.

At least one embodiment of the present disclosure further provides a display device including the display panel provided by any of the above embodiments.

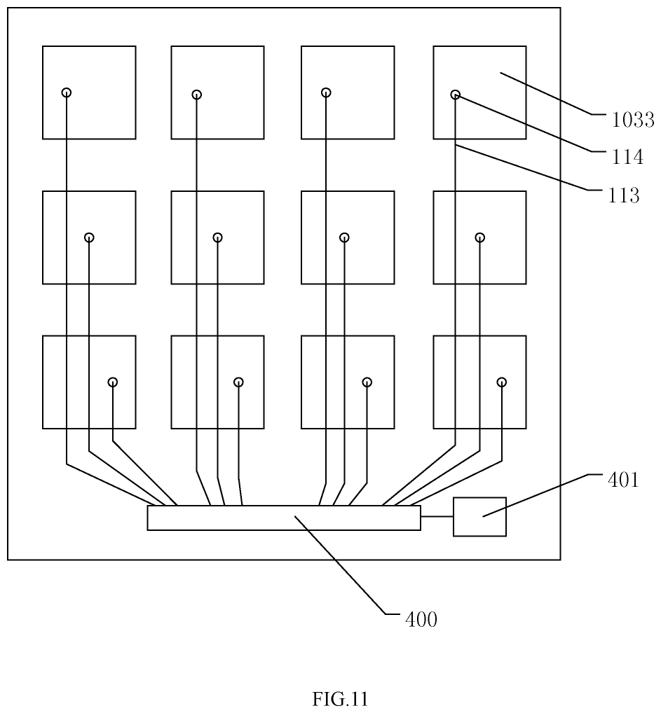

FIG. 11 is a schematic diagram of block control of a display device according to at least one embodiment of the present disclosure. The display device further includes a controller 400 and a photosensitive element 401. The controller 400 is located at a periphery of a display region and is electrically connected to the photosensitive element 401 and the dielectric elastomer 1033 respectively; the photosensitive element 401 can be located in the display region or outside the display region, provided that it can receive ambient light. The photosensitive element 401 is configured to detect the ambient light intensity and provide a light intensity signal to the controller 400, and the controller 400 applies a corresponding voltage to the dielectric elastomer block 1033 according to the light intensity signal. The controller 400 is connected to the array substrate, for example, through a bonding region and a flexible circuit board, and each of the control lines 113 of the array substrate is electrically connected to the controller 400. The controller 400 is, for example, an integrated circuit (IC) chip.

By connecting each of the dielectric elastomer blocks to the controller respectively, each of the dielectric elastomer blocks can be controlled independently, so as to adjust reflectivity of different positions of the display device. In addition, the photosensitive element can provide an ambient light intensity signal to the controller, so that the reflectivity can be adjusted more adaptable to the environment, thereby optimizing the display effect.

The display device can be implemented, for example, as any product or component with a display function, such as a liquid crystal panel, an electronic paper, a mobile phone, a tablet computer, television, a display, a notebook computer, a digital photo frame, a navigator, etc.

At least one embodiment of the present disclosure further provides a display method of the display device provided by the above embodiments, including the following steps:

S1: detecting the ambient light intensity through the photosensitive element 401;

S2: applying a corresponding voltage to the dielectric elastomer 103 according to the detected ambient light intensity to change the unevenness of the surface on one side of the dielectric elastomer 103 close to the reflective layer 102, thereby changing the reflectivity of the reflective layer 102.

In some examples, the display device is a transflective display device, that is, at least one of the plurality of pixel units P of the display device includes the transmissive region P2. The display device further includes a backlight unit, which is connected to the controller 400, and the backlight unit is switched on or off by the controller 400. In this case, in the above step S2, applying a corresponding voltage to the dielectric elastomer 103 according to the detected ambient light intensity includes:

S21: when the ambient light intensity is less than a first preset light intensity, switching on the backlight unit and stopping applying voltage to the dielectric elastomer 103.

When the ambient light intensity is less than the first preset light intensity, the controller 400 determines that the display device is in a dark environment, starts a transmissive mode, stops applying voltage to the dielectric elastomer 103, switches on the backlight unit, and displays an image by the light provided by the backlight unit.

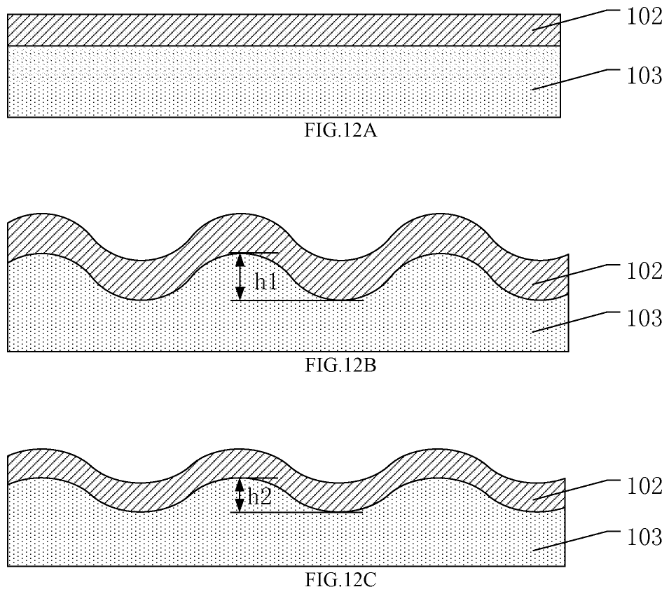

FIG. 12A is a schematic structural diagram of the dielectric elastomer and the reflective layer when no voltage is applied to the dielectric elastomer according to at least one embodiment of the present disclosure. For clear and simple description, only the dielectric elastomer 103 and the reflective layer 102 are illustrated in the figure. In this case, as illustrated in FIG. 12A, the dielectric elastomer 103 and the reflective layer 102 are in a planar state. In this case, the surface of the reflective layer is planar and has a low reflectivity, and in this state, the backlight unit can be applied for display.

In some examples, in the above step S2, applying a corresponding voltage to the dielectric elastomer 103 according to the detected ambient light intensity includes:

S22: when the ambient light intensity is greater than or equal to the first preset light intensity and less a the second preset light intensity, applying a voltage in a first voltage range to the dielectric elastomer, so that the unevenness of the surface of the dielectric elastomer is greater than a preset unevenness;

S23: when the ambient light intensity is greater than or equal to the second preset light intensity, applying a voltage in a second voltage range to the dielectric elastomer, so that the unevenness of the surface of the dielectric elastomer is less than the preset unevenness.

For example, the second preset light intensity is greater than the first preset light intensity, and the voltage value in the first voltage value range is greater than the voltage value in the second voltage value range. The numerical value or range of the first preset light intensity and the second preset light intensity, the first voltage value range and the second voltage value range, and the preset unevenness can be obtained by calculation, test or experience, which are not limited in the present disclosure.

In the case of S22, that is, when the ambient light intensity is greater than or equal to the first preset light intensity and less than the second preset light intensity, the controller 400 determines that the display device is in a situation where the ambient light is insufficient. In this case, the controller 400 increases the reflectivity of the array substrate by applying a voltage in the first voltage range to the dielectric elastomer 103, thereby increasing the brightness of the display device.

For example, FIG. 12B is a schematic structural diagram of the dielectric elastomer and the reflective layer when a voltage in the first voltage range is applied to the dielectric elastomer. In this case, as illustrated in FIG. 12B, the dielectric elastomer 103 and the reflective layer 102 are in a first protrusion state. In this case, the unevenness of the surface of the reflective layer 102 is large, and thus the reflectivity is high.

In the case of S23, that is, when the ambient light intensity is greater than or equal to the second preset light intensity, the controller 400 determines that the display device is in a situation where the ambient light is sufficient. In this case, the controller 400 reduces the reflectivity of the array substrate by applying a voltage in the second voltage range to the dielectric elastomer 103, thereby reducing the brightness of the display device, so as to prevent from irritating eyes due to excessive brightness.

FIG. 12C is a schematic diagram of a protrusion of the dielectric elastomer and the reflective layer when a voltage in the second voltage range is applied to the dielectric elastomer according to at least one embodiment of the present disclosure. In this case, as illustrated in FIG. 12C, the dielectric elastomer 103 is in a second protrusion state, and a height h1 of the first protrusion is greater than a height of the second protrusion h2. In this case, the unevenness of the surface of the reflective layer 102 is proper, and thus the reflectivity is proper. It is prevented from irritating the eyes due to excessively high intensity reflected light, while the reflection light is fully utilized to display.

The following statements should be noted:

(1) The accompanying drawings involve only the structure(s) in connection with the embodiment(s) of the present disclosure, and other structure(s) can be referred to common design(s).

(2) In case of no conflict, features in one embodiment or in different embodiments can be combined.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. An array substrate, comprising:
a base substrate;
a plurality of pixel units on the base substrate, at least one of the plurality of pixel units comprising a reflective layer; and
a dielectric elastomer, on a side of the reflective layer close to the base substrate, and configured to change an unevenness of a surface on a side close to the reflective layer under a voltage, thereby changing an unevenness of the reflective layer.

2. The array substrate of claim 1, wherein the reflective layer is conformally formed on the dielectric elastomer.

3. The array substrate of claim 1, wherein the at least one of the plurality of pixel units further comprises a transmissive region located outside the reflective layer.

4. The array substrate of claim 1, further comprising a control line, electrically connected to the dielectric elastomer, and configured to apply a voltage to the dielectric elastomer.

5. The array substrate of claim 4, wherein the dielectric elastomer comprises a plurality of dielectric elastomer blocks arranged in an array, and each of the dielectric elastomer blocks is in a region where at least one pixel unit is located, the control line comprises a plurality of control lines, and each of the dielectric elastomer blocks is connected to at least one of the plurality of control lines.

6. The array substrate of claim 3, wherein the dielectric elastomer is provided with a light transmitting region in a region corresponding to the transmissive region.

7. The array substrate of claim 4, wherein the dielectric elastomer comprises a conductive layer and a dielectric elastic material layer which are stacked,
the conductive layer is electrically connected to the control line, and is configured to apply a voltage to the dielectric elastic material layer,
the dielectric elastic material layer is configured to change an unevenness of a surface on a side away from the base substrate according to the voltage applied by the conductive layer.

8. The array substrate of claim 7, wherein the conductive layer comprises a first conductive layer and a second conductive layer, respectively located on two sides of the dielectric elastic material layer in a direction perpendicular to the base substrate, one of the first conductive layer and the second conductive layer is electrically connected to the control line, and the other of the first conductive layer and the second conductive layer is configured to apply a common voltage.

9. The array substrate of claim 1, wherein changing the unevenness of the surface close to the reflective layer comprises forming a protrusion or changing a height of the protrusion.

10. The array substrate of claim 1, wherein the reflective layer is a color reflective layer.

11. The array substrate of claim 1, wherein the dielectric elastomer and the reflective layer are insulated from each other.

12. A display device comprising the array substrate according to claim 1.

13. The display device of claim 12, further comprising a controller and a photosensitive element, wherein the controller is respectively electrically connected to the photosensitive element and the dielectric elastomer,
the photosensitive element is configured to detect ambient light intensity and provide a light intensity signal to the controller, and the controller applies a corresponding voltage to the dielectric elastomer according to the light intensity signal.

14. A display method of the display device according to claim 13, comprising:
detecting the ambient light intensity;
applying a corresponding voltage to the dielectric elastomer according to the ambient light intensity to change an unevenness of a surface on a side of the dielectric elastomer close to the reflective layer, thereby changing reflectivity of the reflective layer.

15. The display method of claim 14, wherein the at least one of the plurality of pixel units comprises a transmissive region, and the display device further comprises a backlight unit,
applying a corresponding voltage to the dielectric elastomer according to the ambient light intensity comprises:
in a case that the light intensity is less than a first preset light intensity, switching on the backlight unit and stopping applying the voltage to the dielectric elastomer;
in a case that the light intensity is greater than or equal to the first preset light intensity and less than a second preset light intensity, applying a voltage in a first voltage range to the dielectric elastomer, so that the unevenness of the surface of the dielectric elastomer is greater than a preset unevenness;
in a case that the light intensity is greater than or equal to the second preset light intensity, applying a voltage in a second voltage range to the dielectric elastomer, so that the unevenness of the surface of the dielectric elastomer is less than the preset unevenness,
wherein the second preset light intensity is greater than the first preset light intensity, and a voltage value in the first voltage value range is greater than a voltage value in the second voltage value range.

16. The array substrate of claim 2, wherein the at least one of the plurality of pixel units further comprises a transmissive region located outside the reflective layer.

17. The array substrate of claim 2, further comprising a control line, electrically connected to the dielectric elastomer, and configured to apply a voltage to the dielectric elastomer.

18. The array substrate of claim 4, wherein the dielectric elastomer is provided with a light transmitting region in a region corresponding to the transmissive region.

19. The array substrate of claim 5, wherein the dielectric elastomer comprises a conductive layer and a dielectric elastic material layer which are stacked,
the conductive layer is electrically connected to the control line, and is configured to apply a voltage to the dielectric elastic material layer,
the dielectric elastic material layer is configured to change an unevenness of a surface on a side away from the base substrate according to the voltage applied by the conductive layer.

20. The array substrate of claim 2, wherein changing the unevenness of the surface close to the reflective layer comprises forming a protrusion or changing a height of the protrusion.
